(19) United States
(12) Patent Application Publication
(10) Pub. No.: US 2025/0183146 A1
(43) Pub. Date: Jun. 5, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: JUNGHOON KANG, Suwon-si (KR)

(21) Appl. No.: 18/746,790

(22) Filed: Jun. 18, 2024

(30) Foreign Application Priority Data
Dec. 5, 2023 (KR) 10-2023-0174434

(51) Int. Cl. H01L 23/498; H01L 21/48; H01L 21/56; H01L 23/00; H01L 23/31; H01L 23/367; H01L 25/065; H01L 25/18; H10B 80/00

(52) U.S. Cl. CPC H01L 23/49838; H01L 21/4871; H01L 21/56; H01L 23/3128; H01L 23/3672; H01L 23/49866; H01L 24/08; H01L 24/16; H01L 25/0655; H01L 25/18; H01L 2224/08235; H01L 2224/16227; H01L 2924/1436; H01L 2924/1815; H10B 80/00

(57) ABSTRACT

A semiconductor package including a lower redistribution structure; a solder resist layer that is disposed on a lower surface of the lower redistribution structure; a connection structure that includes a cavity overlapping a portion of the lower redistribution structure and is disposed on the lower redistribution structure; a first semiconductor device that is accommodated inside the cavity; an encapsulation layer that covers a side surface of the first semiconductor device and an upper surface of the connection structure; a first heat dissipation member that is disposed directly on the first semiconductor device; a second heat dissipation member that is disposed directly on the first heat dissipation member; and a second semiconductor device that is disposed on the upper surface of the connection structure.

### CROSS-REFERENCE TO RELATED APPLICATION

This application is based on and claims priority under 35 U.S.C. § 119 to Korean Patent Application No. 10-2023-0174434 filed at the Korean Intellectual Property Office on Dec. 5, 2023, the entire content of which is incorporated herein by reference.

### BACKGROUND

### 1. Field

The present disclosure relates to a semiconductor package and a method for manufacturing (fabricating) the same.

### 2. Description of the Related Art

In the semiconductor industry, modifications to provide for a reduction in weight, reduced thickness, miniaturization, increase in speed, and multifunctionalization of a semiconductor package that protects a semiconductor chip at which an integrated circuit is formed are currently being pursued. If the semiconductor package becomes lighter, thinner, miniaturized, faster, and multi-functional, an electric power consumed per unit volume of the semiconductor package increases so that a temperature inside the semiconductor package increases. If heat generated in the semiconductor package is not efficiently dissipated in response to an increase in the temperature of the semiconductor package, a difference in thermal stress may occur in the package structure so that warpage in the package occurs, and product reliability may deteriorate because an operating speed of the semiconductor package slows down.

### SUMMARY

A problem to be solved by the present disclosure is to provide a semiconductor package with an improved heat dissipation characteristics.

A semiconductor package according to an embodiment includes: a lower redistribution structure; a solder resist layer that is disposed on a lower surface of the lower redistribution structure; a connection structure that includes a cavity overlapping a portion of the lower redistribution structure and is disposed on the lower redistribution structure; a first semiconductor device that is accommodated inside the cavity; an encapsulation layer that covers a side surface of the first semiconductor device and an upper surface of the connection structure; a first heat dissipation member that is disposed directly on the first semiconductor device and has a lower surface in contact with an upper surface of the first semiconductor device; a second heat dissipation member that is disposed directly on the first heat dissipation member and has a lower surface in contact with an upper surface of the first heat dissipation member; and a second semiconductor device that is disposed on the upper surface of the connection structure.

A method for manufacturing the semiconductor package according to an embodiment includes: forming, on a substrate, a connection structure including a cavity that exposes a portion of an upper surface of the substrate; mounting a first semiconductor device inside the cavity; forming an encapsulation layer covering the first semiconductor device and the connection structure; forming a lower redistribution structure on lower surfaces of the connection structure and the first semiconductor device after the substrate is removed; forming a solder resist layer on a lower surface of the lower redistribution structure; removing some regions of the encapsulation layer that overlap the first semiconductor device in a vertical direction; forming a first heat dissipation member in contact with an upper surface of the first semiconductor device at a region from which the encapsulation layer is removed; forming a second heat dissipation member in contact with an upper surface of the first heat dissipation member; and mounting a second semiconductor device above the connection structure.

A semiconductor package according to another embodiment includes: a lower redistribution structure; a connection structure that includes a cavity overlapping a portion of the lower redistribution structure and is disposed on the lower redistribution structure; a first semiconductor device that is accommodated inside the cavity; a metal pad that is disposed directly on the first semiconductor device and has a lower surface in contact with an upper surface of the first semiconductor device; a first heat dissipation member that is disposed directly on the metal pad and has a lower surface in contact with an upper surface of the metal pad; a second heat dissipation member that is disposed directly on the first heat dissipation member and has a lower surface in contact with an upper surface of the first heat dissipation member; and a second semiconductor device that is disposed on an upper surface of the connection structure.

According to the embodiments, a semiconductor device and a heat dissipation member that are mounted inside a semiconductor package may contact each other so that the semiconductor package with improved heat dissipation efficiency is provided.

### BRIEF DESCRIPTION OF THE DRAWINGS

FIG. 1 is a plan view showing a semiconductor package according to an embodiment.

FIG. 2 is a cross-sectional view showing the semiconductor package according to an embodiment.

FIG. 3 is a cross-sectional view showing a semiconductor package according to an embodiment.

FIGS. 4 to 14 are process cross-sectional views showing a process sequence of manufacturing the semiconductor package according to an embodiment.

### DETAILED DESCRIPTION

Below, embodiments of the present disclosure will be described with reference to accompanying drawings to such an extent as to be easily realized by a person having an ordinary knowledge in the present disclosure. The present disclosure may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side surface of the object portion based on a gravitational direction.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

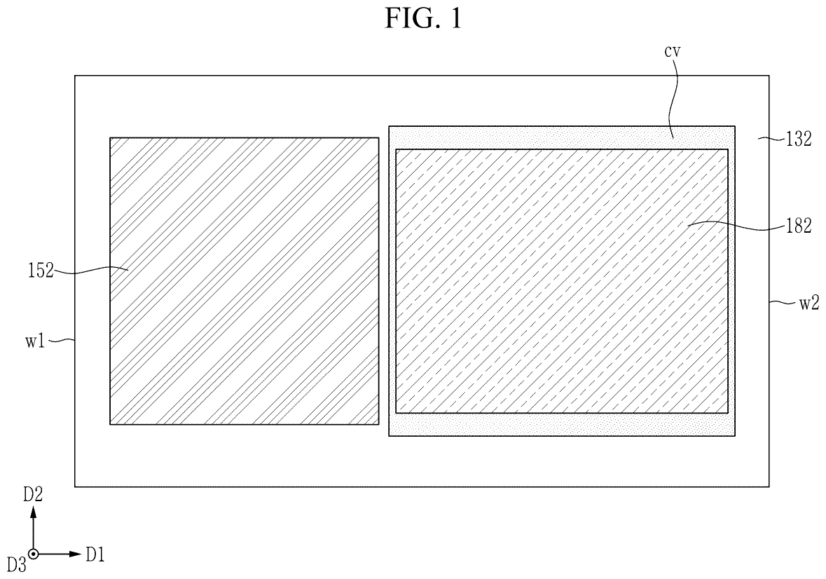

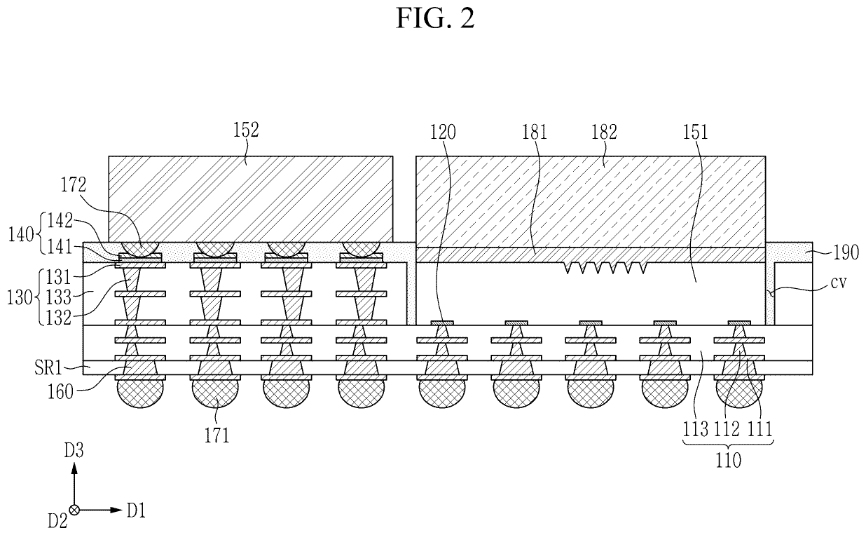

Hereinafter, a semiconductor package according to an embodiment will be described with reference to FIG. 1 and FIG. 2.

FIG. 1 and FIG. 2 are views showing a semiconductor package according to an embodiment. Specifically, FIG. 1 is a plan view showing the semiconductor package according to an embodiment, and FIG. 2 is a cross-sectional view showing the semiconductor package according to an embodiment.

Referring to FIG. 1 and FIG. 2, the semiconductor package according to the embodiment may include a lower redistribution structure 110, a solder resist layer SR1 disposed on a lower surface of the lower redistribution structure 110, a connection structure 130 that is disposed on the lower redistribution structure and includes a cavity cv that exposes a portion of the lower redistribution structure, the first semiconductor device 151 accommodated inside the cavity cv, an encapsulation layer 190 covering a side surface of the first semiconductor device 151 and an upper surface of the connection structure 130, a first heat dissipation member (or a first heat radiating member) 181 disposed directly on (e.g. in contact with) the first semiconductor device 151, a second heat dissipation member 182 disposed directly on (e.g. in contact with) the first heat dissipation member 181, and a second semiconductor device 152 disposed on the upper surface of the connection structure 130.

The lower redistribution structure 110 may support the first semiconductor device 151 that will be described later. The lower redistribution structure 110 may include a lower insulating layer 113, lower redistribution patterns 111 disposed within the lower insulating layer 113, and lower redistribution vias 112. In another embodiment, the lower redistribution structure 110 may include fewer or more lower redistribution patterns 111 and fewer or more lower redistribution vias 112.

The lower insulating layer 113 may be disposed between the lower redistribution patterns 111 and the lower redistribution vias 112 to protect and insulate them. The lower insulating layer 113 may cover the lower redistribution patterns 111 and the lower redistribution vias 112. The lower insulating layer 113 may include an insulating resin. For example, the lower insulating layer 113 may include a thermosetting resin such as an epoxy resin, a thermoplastic resin such as polyimide, or a resin (for example, prepreg, an Ajinomoto Build-up Film (ABF), FR-4, or BT) including the thermosetting resin or the thermoplastic resin impregnated with an inorganic filler or/and a glass fiber (a glass cloth or a glass fabric). The lower insulating layer 113 may include a photosensitivity resin such as a photo-imageable dielectric (PID).

The lower redistribution pattern 111 may provide a path through which various electrical signals necessary for operations of the semiconductor devices 151 and 152 that will be described later are transmitted or received. The plurality of lower redistribution patterns 111 may be disposed in layers within the lower insulating layer 113. For example, the lower redistribution structure 110 may include two or more layers spaced apart in a vertical direction, and the plurality of lower redistribution patterns 111 may be disposed in a horizontal direction within each layer. Referring to FIG. 2, the lower redistribution patterns 111 are shown as including two layers, but the number of layers in which the lower redistribution patterns 111 are disposed is not limited by the embodiment. For example, the lower redistribution pattern 111 may include copper (Cu), aluminum (Al), silver (Ag), tin (Sn), gold (Au), nickel (Ni), lead (Pb), titanium (Ti), or a metal material including an alloy thereof.

The lower redistribution via 112 may electrically connect the lower redistribution patterns 111 spaced apart in a vertical direction. The lower redistribution via 112 may be integrally formed with the lower redistribution patterns 111, but the present disclosure is not limited thereto. The lower redistribution via 112 may include the same material as that of the lower redistribution pattern 111. For example, the lower redistribution via 112 may include copper (Cu), aluminum (Al), silver (Ag), tin (Sn), gold (Au), nickel (Ni), lead (Pb), titanium (Ti), or a metal material including an alloy thereof. However, the present disclosure is not limited thereto, and the lower redistribution via 112 may include a different material from that of the lower redistribution pattern 111.

The solder resist layer SR1 may be disposed on a lower surface of the lower redistribution structure 110. The solder resist layer SR1 may protect the lower redistribution pattern 111 from a physical or chemical damage. The solder resist layer SR1 may include openings that expose some regions of lower surfaces of the lower redistribution patterns 111 disposed at a downmost side of the lower redistribution patterns 111. The solder resist layer SR1 may include an insulating material. For example, the solder resist layer SR1 may include prepreg, an ABF, FR-4, BT, or a photo solder resist (PSR). Under bump metallization (UBM) structures 160 may be disposed in an opening of the solder resist layer SR1. Specifically, the UBM structures 160 may fill each opening formed at the solder resist layer SR1. The UBM structure 160 may include a metal material. For example, the UBM structure 160 may include copper (Cu), aluminum (Al), silver (Ag), tin (Sn), gold (Au), nickel (Ni), lead (Pb), titanium (Ti), or a metal material including an alloy thereof.

Connection bumps 171 connected to one end of the UBM structures 160 may be disposed below the lower redistribution structure 110. The connection bumps 171 may electrically connect the semiconductor package according to the embodiment to an external device (not shown). The connection bumps 171 may be connected to the lower redistribution patterns 111 through the UBM structures 160. The connection bumps 171 may include a metal material. For example, the connection bumps 171 may have a spherical or ball shape made of a low melting point metal such as tin (Sn), indium (In), bismuth (Bi), antimony (Sb), copper (Cu), silver (Ag), zinc (Zn), lead (Pb), an alloy (e.g., Sn—Ag—Cu) thereof, or the like.

The connection structure 130 may be disposed on the lower redistribution structure 110. The connection structure 130 may provide an electrical path connecting the second semiconductor device 152, described later that is mounted above the connection structure 130, to the lower redistribution pattern 111. The connection structure 130 may include an insulating layer 133, wiring patterns 131 disposed within the insulating layer 133, and wiring vias 132. In another embodiment, the connection structure 130 may include fewer or more wiring patterns 131 and fewer or more wiring vias 132.

The insulating layer 133 may be disposed between the wiring patterns 131 and the wiring vias 132 to insulate them. The insulating layer 133 may cover the wiring patterns 131 and the wiring vias 132. The insulating layer 133 may include an insulating resin. For example, the insulating layer 133 may include a thermosetting resin such as an epoxy resin, a thermoplastic resin such as polyimide, or a resin (for example, prepreg or the like) including the thermosetting resin or the thermoplastic resin impregnated with an inorganic filler or/and a glass fiber (a glass cloth or a glass fabric).

The wiring patterns 131 and the wiring vias 132 may provide a path for electrical signals flowing between the lower redistribution structure 110 and the second semiconductor device 152. The wiring pattern 131 may be disposed in layers inside the insulating layer 133. The connection structure 130 may include two or more layers spaced apart in a vertical direction, and the plurality of wiring patterns 131 may be disposed in a horizontal direction within each layer. For example, the wiring pattern 131 may include copper (Cu), aluminum (Al), silver (Ag), tin (Sn), gold (Au), nickel (Ni), lead (Pb), titanium (Ti), or a metal material including an alloy thereof.

In an embodiment, the connection structure 130 may further include a metal pad 140 that covers some regions of upper surfaces of the wiring patterns 131 disposed at an uppermost layer among the wiring patterns 131. The metal pad 140 may prevent surface oxidation of the wiring pattern 131, and may protect the wiring pattern 131 from an external physical impact. The metal pad 140 may include at least two or more metal layers. For example, referring to FIG. 2, the metal pad 140 may include a first metal pad 141 that covers a portion of an upper surface of the wiring pattern 131 disposed at an uppermost layer, and a second metal pad 142 that covers an upper surface of the first metal pad 141. In an embodiment, the wiring pattern 131 and metal pads 140 may have a circular shape with a diameter having a predetermined length, but the shape of the wiring pattern 131 and the metal pad 140 is not limited thereto. In an embodiment, a width of the metal pad 140 along a horizontal direction (e.g., a first direction D1 or a second direction D2) may be smaller than a width of the wiring pattern 131 along a horizontal direction (e.g., the first direction D1 or the second direction D2). In an embodiment, widths of the first metal pad 141 and the second metal pad 142 along the horizontal direction (the first direction D1 or the second direction D2) may be the same. For example, a width of the wiring pattern 131 along the horizontal direction (the first direction D1 or the second direction D2) may be about 290 μm. For example, the widths of the first metal pad 141 and the second metal pad 142 along the horizontal direction (the first direction D1 or the second direction D2) may be about 260 μm. Although not clearly shown in FIG. 2, thicknesses (i.e., widths along a third direction D3) of the first metal pad 141 and the second metal pad 142 may be less than or equal to a thickness of the wiring pattern 131. Additionally, the thickness of the second metal pad 142 may be smaller than the thickness of the first metal pad 141. For example, a thickness (i.e., height) of the wiring pattern 131 may be about 2 μm to about 15 μm. For example, a height of the first metal pad 141 may be about 2 μm to about 8 μm. For example, a thickness (i.e., height) of the second metal pad 142 may be about 0.1 μm to 0.9 μm. The metal pad 140 may include a conductive material. For example, the first metal pad 141 may include nickel (Ni). For example, the second metal pad 142 may include gold (Au).

The wiring vias 132 may electrically connect the wiring patterns 131 disposed to be spaced apart from each other in a vertical direction inside the insulating layer 133. The wiring via 132 may include the same material as that of the wiring pattern 131. For example, the wiring via 132 may include copper (Cu), aluminum (Al), silver (Ag), tin (Sn), gold (Au), nickel (Ni), lead (Pb), titanium (Ti), or a metal material including an alloy thereof. However, the present disclosure is not limited thereto, and the wiring via 132 may include a different material from that of the wiring pattern 131.

In an embodiment, the connection structure 130 may include the cavity cv. The cavity cv may mean an empty space for mounting the first semiconductor device 151 inside the connection structure 130. That is, the insulating layer 133, the wiring patterns 131, and the wiring vias 132 may not be disposed at a region where the cavity cv is formed. Accordingly, a portion of an upper surface of the lower redistribution structure 110 may be exposed through the cavity cv. A width of the cavity cv along the horizontal direction may be slightly larger than a width of the first semiconductor device 151 along the horizontal direction. A height of the cavity cv may be slightly larger than a height of the first semiconductor device 151. In an embodiment, the cavity cv may be disposed to be closer to one of two facing outer walls of the connection structure 130 along the horizontal direction. In other words, referring to FIG. 1, the connection structure 130 may include a first sidewall w1 and a second sidewall w2 facing the first sidewall w1, and the cavity cv may be closer to the second sidewall w2 than to the first sidewall w1. Accordingly, more space for mounting the second semiconductor device 152 described later that is disposed on the connection structure 130 may be secured compared with a case where the cavity cv is formed centrally within the connection structure 130.

The first semiconductor device 151 may be mounted in the cavity cv. The first semiconductor device 151 may be mounted inside the cavity cv using a flip chip method. That is, the first semiconductor device 151 may be mounted inside the cavity cv in a state in which a front side (i.e., active side) faces downward (e.g., in a direction completely opposite to the third direction D3 of FIG. 2). In this case, the active side of the first semiconductor device 151 may be in contact with an upper surface of the lower redistribution structure 110. The first semiconductor device 151 may include two or more connection pads 120 formed at the active side. The first semiconductor device 151 may be electrically connected to the lower redistribution via 112 of the lower redistribution structure 110 through connection pads 120. In an embodiment, the first semiconductor device 151 may include a system on chip (SOC). The first semiconductor device 151 may be an integrated circuit (IC) in a bare state in which no separate bump or wiring layer is formed, but the present disclosure is not limited thereto. The first semiconductor device 151 may be a packaged type integrated circuit. In an embodiment, the first semiconductor device 151 may include a central processing unit (CPU) or a graphics processing unit (GPU). In an embodiment, the first semiconductor device 151 may be a processor chip such as a field programmable gate array (FPGA), an application processor (AP), a digital signal processor, an encryption processor, a microprocessor, a micro-controller, or the like, but the present disclosure is not limited thereto. The first semiconductor device 151 may be a logic chip such as a digital converter, an application-specific IC (ASIC), or the like, or a memory chip such as a volatile memory (e.g., a DRAM), a non-volatile memory (e.g., an ROM or a flash memory), or the like.

In an embodiment, the first semiconductor device 151 may include two or more grooves disposed on an upper surface thereof. If the first semiconductor device 151 is mounted inside the cavity cv in a form of a flip chip, a surface of the first semiconductor device 151 that is opposite to the active side of the first semiconductor device 151 is referred to as an upper surface of the first semiconductor device 151 herein. The grooves may represent (e.g., identify) the first semiconductor device 151, or a serial number of the semiconductor package at which the first semiconductor device 151 is mounted. For example, the grooves may include information for distinguishing the semiconductor package from another semiconductor package during a manufacturing process of the semiconductor package or after the semiconductor package is manufactured. A manufacturing process of each semiconductor package may be managed based on the above information given to each semiconductor package. In an embodiment, the grooves may be engraved on the back side of the first semiconductor device 151 using a laser. In an embodiment, the grooves may have a depth of about 20 nm in a thickness direction from the upper surface of the first semiconductor device 151.

The encapsulation layer 190 may be disposed on the first semiconductor device 151 and the connection structure 130. Specifically, the encapsulation layer 190 may cover the side surface of the first semiconductor device 151 and the upper surface of the connection structure 130. The encapsulation layer 190 may protect the first semiconductor device 151 mounted inside the cavity cv and some regions of the connection structure 130 from an external physical or chemical impact. In an embodiment, the encapsulation layer 190 may not be disposed on the first semiconductor device 151. For example, referring to FIG. 2, the encapsulation layer 190 may not overlap the first semiconductor device 151 in a vertical direction (e.g., the third direction D3). The encapsulation layer 190 may include an insulating material. Specifically, the encapsulation layer 190 may include an insulating resin (e.g., an ABF) including an inorganic filler included in an insulating resin such as an epoxy resin. However, the present disclosure is not limited thereto, and the encapsulation layer 190 may include a photosensitivity resin such as a photo-imageable dielectric (PID).

The first heat dissipation member 181 may be disposed on the first semiconductor device 151. Specifically, the first heat dissipation member 181 may be disposed directly on the first semiconductor device 151, and a lower surface of the first heat dissipation member 181 may be in contact with the upper surface of the first semiconductor device 151. The first heat dissipation member 181 may bond the second heat dissipation member 182 and the first semiconductor device 151 that are described later. In an embodiment, the first heat dissipation member 181 may completely overlap the first semiconductor device 151 in a vertical direction, and the upper surface of the first semiconductor device 151 may be entirely covered by the first heat dissipation member 181. In an embodiment, a width of the first heat dissipation member 181 along the horizontal direction (the first direction D1 or the second direction D2) may be substantially the same as a width of the first semiconductor device 151 along the horizontal direction (the first direction D1 or the second direction D2). In an embodiment, the first heat dissipation member 181 may have a lower surface having a planar shape that is substantially the same as the upper surface of the first semiconductor device 151.

The first heat dissipation member 181 may include a material that has high thermal conductivity and adhesiveness. For example, the first heat dissipation member 181 may include a thermal interface material (TIM) such as a thermal conductive adhesive. For example, the thermal conductive adhesive may be an epoxy resin-based adhesive, a silicon-based adhesive, or the like. In an embodiment, a thickness of the first heat dissipation member 181 may be about 0.07 mm to about 0.1 mm.

In an embodiment, the first heat dissipation member 181 may include protrusions corresponding to the grooves disposed on the upper surface the first semiconductor device 151. For example, a protrusion may be disposed in a respective groove such that the protrusions of the first heat dissipation member 181 may fill the grooves disposed at the back side of the first semiconductor device 151. That is, in an embodiment, the first heat dissipation member 181 may include a material with ductility. Accordingly, if the lower surface of the first heat dissipation member 181 is in contact with the upper surface of the first semiconductor device 151 as shown in FIG. 2, the first heat dissipation member 181 may fill the grooves formed on the upper surface of the first semiconductor device 151.

The second heat dissipation member 182 may be disposed on the first heat dissipation member 181. Specifically, the second heat dissipation member 182 may be disposed directly on the first heat dissipation member 181, and a lower surface of the second heat dissipation member 182 may contact an upper surface of the first heat dissipation member 181. Referring to FIG. 2, the second heat dissipation member 182 may be disposed adjacent to the second semiconductor device 152 that will be described later in the horizontal direction (the first direction D1 of FIG. 2). The second heat dissipation member 182 may have substantially the same height as that of the second semiconductor device 152. For example, the upper surface of the second heat dissipation member 182 may be disposed at substantially the same vertical level (i.e., in the third direction D3) as that of the upper surface of the second semiconductor device 152

The second heat dissipation member 182 may discharge heat generated from the first semiconductor device 151 and the second semiconductor device 152 to the outside surface of the semiconductor package if the first semiconductor device 151 and the second semiconductor device 152 operate. In an embodiment, the second heat dissipation member 182 may completely overlap the first heat dissipation member 181 in a vertical direction, and the upper surface of the first heat dissipation member 181 may be entirely covered by the second heat dissipation member 182. In an embodiment, the second heat dissipation member 182 may completely overlap the first semiconductor device 151 in the vertical direction. In an embodiment, the second heat dissipation member 182 may be adjacent to a side surface of the second semiconductor device 152. In an embodiment, a width of the second heat dissipation member 182 along the horizontal direction (the first direction D1 or the second direction D2) may be substantially the same as a width of the first heat dissipation member 181 along the horizontal direction (the first direction D1 or the second direction D2). In an embodiment, the second heat dissipation member 182 may have a lower surface having a planar shape that is substantially the same as the upper surface of the first heat dissipation member 181.

In an embodiment, the second heat dissipation member 182 may include a heat slug. The heat slug may be referred to as a heat sink or a heat spreader. The heat slug may include a metal material such as copper (Cu), aluminum (Al), or an alloy thereof. However, the present disclosure is not limited thereto, and a material with high thermal conductivity may be used as a material for forming the second heat dissipation member 182 without limitation. In another embodiment, unlike the embodiment shown in FIG. 2, the widths of the first heat dissipation member 181 and the second heat dissipation member 182 along the horizontal direction (the first direction D1 or the second direction D2) may be different from the width of the first semiconductor device 151 along the horizontal direction (the first direction D1 or the second direction D2). For example, the widths of the first heat dissipation member 181 and the second heat dissipation member 182 along the horizontal direction (the first direction D1 or the second direction D2) may be slightly less than the width of the first semiconductor device 151 along the horizontal direction (the first direction D1 or the second direction D2). In this case, a region that does not overlap the first heat dissipation member 181 in the vertical direction (e.g., the third direction D3) on the upper surface of the first semiconductor device 151 may be covered by the encapsulation layer 190. That is, in this case, the first semiconductor device 151 may have a region that partially overlaps the encapsulation layer 190 in the vertical direction (e.g., the third direction D3).

The second semiconductor device 152 may be disposed at an upper portion of the connection structure 130. The second semiconductor device 152 may be mounted on the upper surface of the connection structure 130 using a flip chip method. That is, the second semiconductor device 152 may be disposed on the upper surface of the connection structure 130 in a state in which a front side (i.e., active side) faces downward (e.g., in a direction completely opposite to the third direction D3 of FIG. 2). The second semiconductor device 152 may include two or more connection bumps 172 formed at the active side thereof. The second semiconductor device 152 may be electrically connected to the wiring patterns 131 of the connection structure 130 through the connection bumps 172. In an embodiment, each connection bump 172 may contact each of the metal pads 140 that cover a surface of the wiring pattern 131 disposed at an uppermost layer of the wiring patterns 131. For example, the connection bumps 172 may contact second metal pads 142. Referring to FIG. 2, some regions of a lower surface of the second semiconductor device 152 and each of the connection bumps 172 may be surrounded by the encapsulation layer 190. In an embodiment, the second semiconductor device 152 may include a memory chip. For example, the second semiconductor device 152 may include a single chip such as a DRAM or a multi-chip such as a high bandwidth memory (HBM).

As described with reference to FIG. 1 and FIG. 2, in the semiconductor package according to the embodiment, the first semiconductor device 151 and the second semiconductor device 152 may be disposed so as not to overlap each other in a thickness direction (i.e., a vertical direction (third direction D3)). In this case, heat generated from the first semiconductor device 151 and the second semiconductor device 152 may be distributed without overlapping each other, so that a heat dissipation characteristic of the semiconductor package is improved.

In the semiconductor package according to the embodiment, the first semiconductor device 151 may not overlap the encapsulation layer 190 in the vertical direction. For example, as shown in FIG. 2, the upper surface of the first semiconductor device 151 may be in contact with the first heat dissipation member 181 having high thermal conductivity, and the encapsulation layer 190 may not be disposed between the upper surface of the first semiconductor device 151 and the first heat dissipation member 181 and/or the second heat dissipation member 182. In general, the encapsulation layer 190 may include an organic material with low thermal conductivity. As shown in FIG. 2, by disposing the first semiconductor device 151 so as not to overlap the encapsulation layer 190 in a vertical direction, heat generated during an operation of the first semiconductor device 151 may be effectively discharged to the outside through the first heat dissipation member 181 and the second heat dissipation member 182.

Although not illustrated, in an embodiment in which the widths of the first heat dissipation member 181 and the second heat dissipation member 182 along the horizontal direction (the first direction D1 or the second direction D2) may be slightly less than the width of the first semiconductor device 151 along the horizontal direction (the first direction D1 or the second direction D2), the encapsulation layer 190 may still not be disposed between the upper surface of the first semiconductor device 151 and the first heat dissipation member 181. For example, in an embodiment in which a region of the first semiconductor device 151 partially overlaps the encapsulation layer 190 in the vertical direction (e.g., the third direction D3), the first heat dissipation member 181 may contact the first semiconductor device 151 in another region such that the encapsulation layer 190 is not disposed between the first heat dissipation member 181 and the first semiconductor device 151 in the vertical direction.

In the semiconductor package according to the embodiment, the heat dissipation members 181 and 182 may be disposed adjacent to the first semiconductor device 151 and the second semiconductor device 152. Specifically, the first semiconductor device 151 may overlap the first and second heat dissipation members 181 and 182 in a vertical direction, and a lower surface of the first semiconductor device 151 may be in contact with a lower surface of the first heat dissipation member 181. Additionally, the second semiconductor device 152 may be adjacent to the first and second heat dissipation members 181 and 182 in the first direction D1. Accordingly, heat generated during operations of the first semiconductor device 151 and the second semiconductor device 152 may be effectively dissipated to the outside through the first heat dissipation member 181 and the second heat dissipation member 182, so that the heat dissipation characteristic of the semiconductor package may be improved.

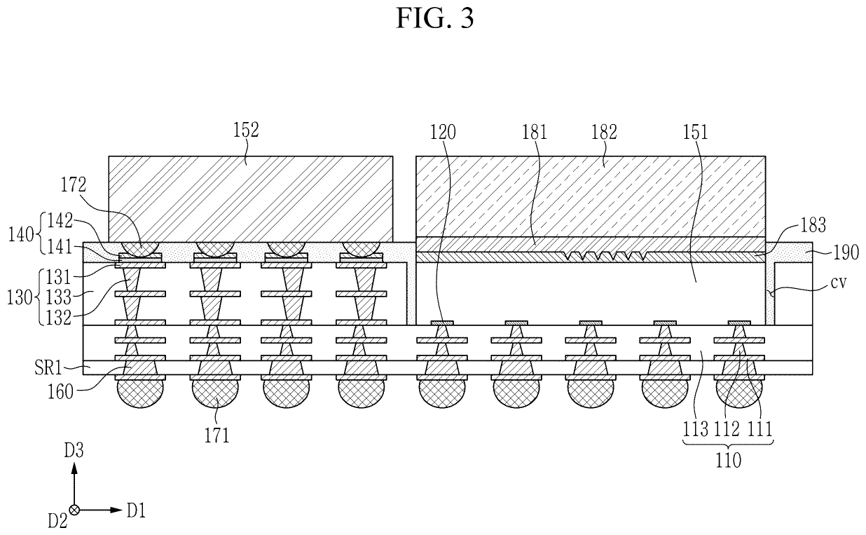

FIG. 3 is a cross-sectional view showing a semiconductor package according to an embodiment. Because the embodiment shown in FIG. 3 includes the same portion as that of the embodiment shown in FIG. 1 and FIG. 2, a description thereof will be omitted, and a difference between the embodiment shown in FIG. 3 and the embodiment shown in FIG. 1 and FIG. 2 will be mainly described. Unlike the previous embodiments, the embodiment shown in FIG. 3 may further include a metal pad 183 disposed on the first semiconductor device 151.

Specifically, referring to FIG. 3, the semiconductor package according to the embodiment may further include the metal pad 183 disposed between the first semiconductor device 151 and the first heat dissipation member 181. In an embodiment, the metal pad 183 may be disposed directly on the first semiconductor device 151, and may overlap the first semiconductor device 151 in a vertical direction. The metal pad 183 may have a lower surface in contact with an upper surface of the first semiconductor device 151. Referring to FIG. 3, a width of the metal pad 183 along a horizontal direction (e.g., a first direction D1 or a second direction D2) may be substantially the same as a width of the first semiconductor device 151 along the horizontal direction (e.g., the first direction D1 or the second direction D2). However, the present disclosure is not limited thereto, and the metal pad 183 may have a width smaller than the width of the first semiconductor device 151 along the horizontal direction (e.g., the first direction D1 or the second direction D2). The metal pad 183 may include a metal material such as copper (Cu), aluminum (Al), or the like. For example, the metal pad 183 may be formed on the upper surface of the first semiconductor device 151 by sputtering or the like. However, the present disclosure is not limited thereto, and the metal pad 183 may be formed on the upper surface of the first semiconductor device 151 by various deposition methods for forming a metal layer.

In an embodiment, the metal pad 183 may include two or more grooves formed on an upper surface thereof. That is, in the semiconductor package described with reference to FIG. 1 and FIG. 2, the grooves may be formed directly on the upper surface of the first semiconductor device 151, but in the semiconductor package according to the embodiment, the grooves may be formed on the upper surface of the metal pad 183 formed on the first semiconductor device 151. The first heat dissipation member 181 may be disposed on the metal pad 183. The metal pad 183 may have an upper surface in contact with a lower surface of the first heat dissipation member 181. The grooves formed at the upper surface of the metal pad 183 may be filled with the first heat dissipation member 181.

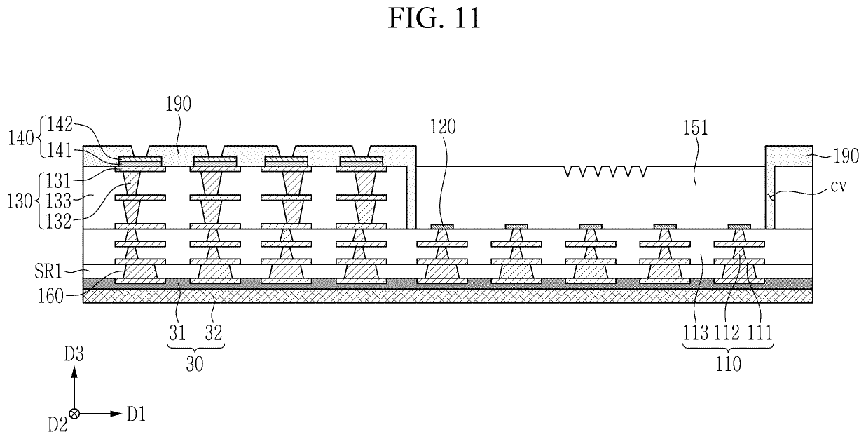

If a groove is formed by irradiating a laser directly to the upper surface of the first semiconductor device 151, semiconductor elements included in the first semiconductor device 151 may be damaged depending on an intensity or a wavelength of laser light, a light absorption rate with respect to a wavelength band of materials included in the first semiconductor device 151, or the like. In addition, as described in FIG. 11, if the encapsulation layer 190 is removed using a laser in a manufacturing process of the semiconductor package according to the embodiment, the semiconductor elements included in the first semiconductor device 151 may be damaged depending on the intensity or the wavelength of laser light, the light absorption rate with respect to the wavelength band of the materials included in the first semiconductor device 151, or the like.

If the metal pad 183 is disposed directly on the first semiconductor device 151 as shown in FIG. 3, the laser may be prevented from being directly irradiated to the first semiconductor device 151 in the process of irradiating the laser so that the embodiment of FIG. 3 prevents the semiconductor elements included in the first semiconductor device 151 from being damaged by the laser light.

In addition, if the grooves are formed on the upper surface of the metal pad 183, a metal material (e.g., aluminum (Al) or copper (Cu)) may generally have high reflectivity to light compared with another material (e.g., silicon (Si)), so that visibility of a serial number of the semiconductor package indicated by the grooves is improved.

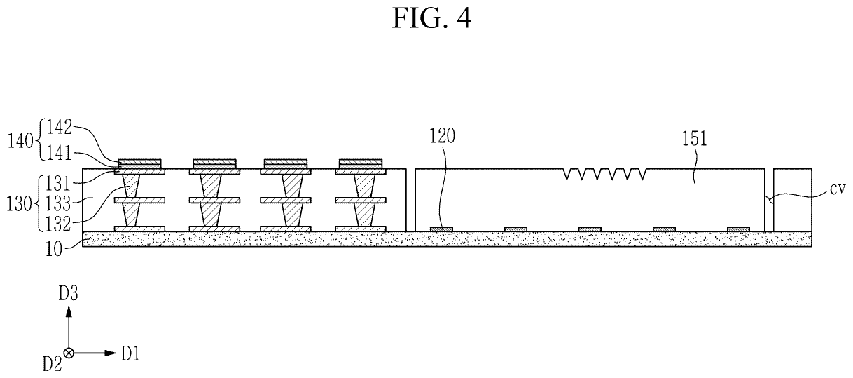

FIGS. 4 to 15 are process cross-sectional views showing a process sequence of manufacturing the semiconductor package according to an embodiment.

First, as shown in FIG. 4, the first semiconductor device 151 and the connection structure 130 may be disposed on a first carrier 10. The first carrier 10 may be a temporary carrier having adhesiveness, and may support the first semiconductor device 151 and the connection structure 130. The first semiconductor device 151 may be disposed in the cavity cv surrounded by the connection structure 130 (e.g., the insulating layer 133 of the connection structure 130). In an embodiment, the cavity cv may be disposed to be closer to one of two facing outer walls of the connection structure 130 along the horizontal direction. In an embodiment, the connection structure 130 may further include the metal pad 140 that covers portions of the upper surfaces of the wiring patterns 131 disposed at the uppermost layer among the wiring patterns 131. The metal pad 140 may include the first metal pad 141 that covers the portion of the upper surface of the wiring pattern 131 disposed at the uppermost layer, and the second metal pad 142 that covers the upper surface of the first metal pad 141. The metal pad 140 may include a conductive material. For example, the first metal pad 141 may include nickel (Ni). For example, the second metal pad 142 may include gold (Au). In an embodiment, the first metal pad 141 and the second metal pad 142 may be formed above or on the wiring pattern 131 by a plating method. For example, the first metal pad 141 and the second metal pad 142 may be formed above or on the wiring pattern 131 by an electroplating method or an electroless plating method.

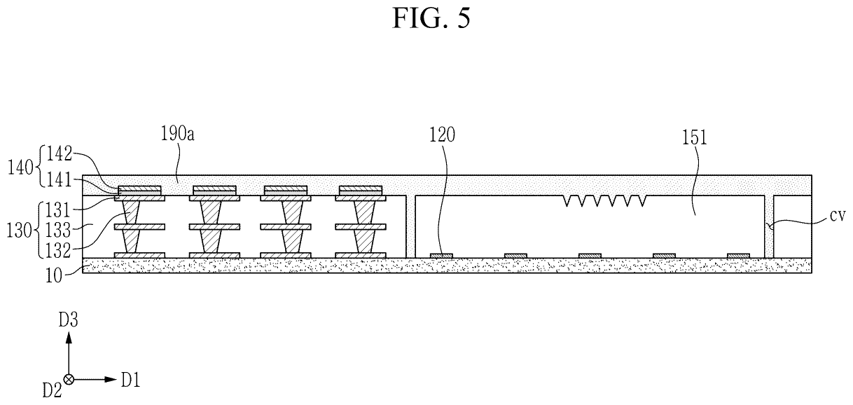

As shown in FIG. 5, a preliminary encapsulation layer 190a covering the first semiconductor device 151 and the connection structure 130 may be formed. In an embodiment, the preliminary encapsulation layer 190a may be formed by transferring a film-type insulating resin such as an Ajinomoto Build-up Film (ABF) on the first semiconductor device 151 and the connection structure 130. In an embodiment, the preliminary encapsulation layer 190a may be formed by applying a photosensitivity resin such as a photo-imageable dielectric (PID) on the first semiconductor device 151 and the connection structure 130.

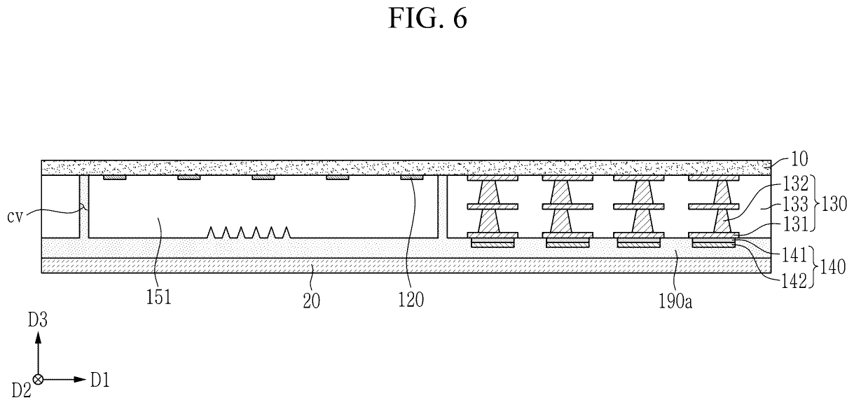

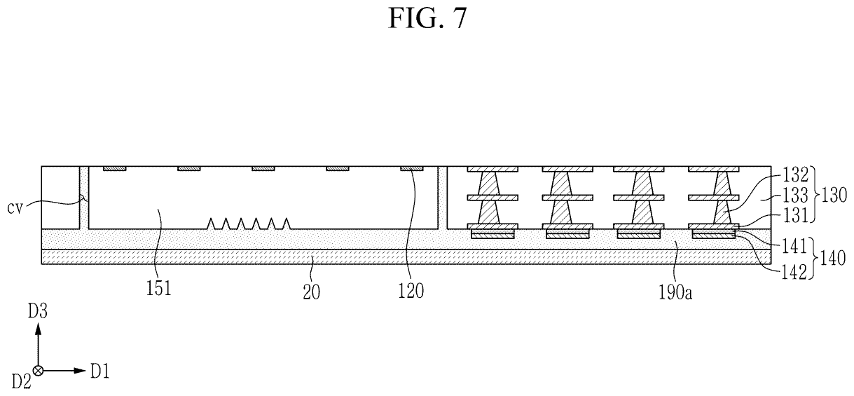

As shown in FIG. 6, the semiconductor package having the preliminary encapsulation layer 190a formed therein may be attached to a second carrier 20. In this case, the semiconductor package may be turned over so that a front side of the preliminary encapsulation layer 190a faces downward, and then the semiconductor package may be attached to the second carrier 20 so that the front side of the preliminary encapsulation layer 190a and an upper surface of the second carrier 20 contact each other. Accordingly, a lower surface (i.e., active surface) of the first semiconductor device 151 and a lower surface of the connection structure 130 may face upward (e.g., in the third direction D3 of FIG. 7).

Subsequently, as shown in FIG. 7, the first carrier 10 may be detached from the semiconductor package. After the first carrier 10 is removed from the semiconductor package, a cleaning process may be further performed to remove a foreign substance remaining in a region where the first carrier 10 is attached.

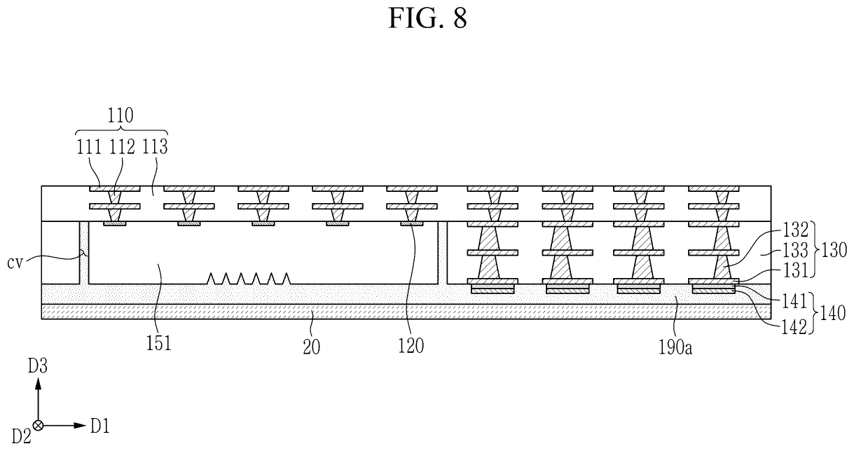

As shown in FIG. 8, the lower redistribution structure 110 may be formed on the lower surface of the first semiconductor device 151 and the lower surface of the connection structure 130. First, a single lower insulating layer 113 may be formed on the lower surface of the first semiconductor device 151 and the lower surface of the connection structure 130. In an embodiment, the lower insulating layer 113 may include an insulating material such as a photo-imageable dielectric (PID). Thereafter, the insulating layer may be patterned to expose some regions of the connection pad 120 disposed on the lower surface of the first semiconductor device 151 and some regions of a lower surface of the wiring pattern 131 disposed at a lowermost layer of the connection structure 130. Thereafter, the lower redistribution via 112 and the lower redistribution pattern 111 may be formed by an electroplating process or an electroless plating process. The process of forming the lower insulating layer 113, the lower redistribution via 112, and the lower redistribution pattern 111 may be repeated several times to form the lower redistribution structure 110 including two or more lower redistribution patterns 111 spaced apart in a vertical direction and the lower redistribution vias 112 connecting the redistribution patterns 111.

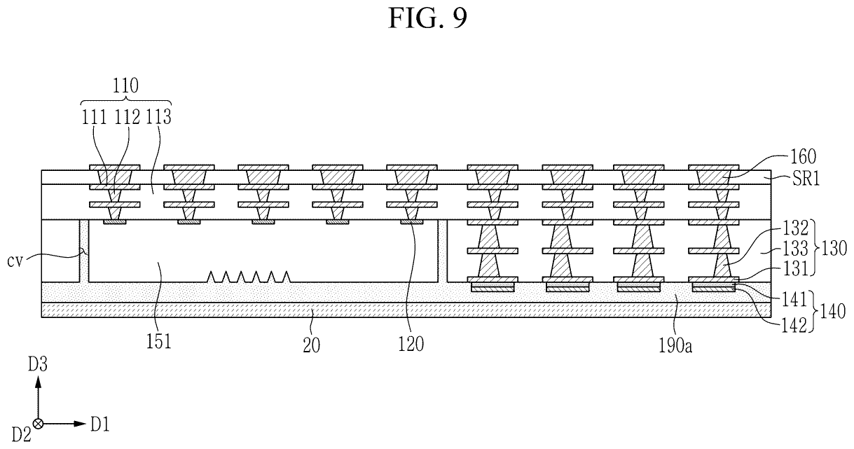

As shown in FIG. 9, the solder resist layer SR1 and the UBM structure 160 filling an opening formed in the solder resist layer SR1 may be formed on the lower redistribution structure 110. First, the solder resist layer SR1 may be formed on the lower surface of the lower redistribution structure 110. In this case, the solder resist layer SR1 may be formed by transferring a film-type insulating resin such as an Ajinomoto Build-up Film (ABF) on the lower surface of the lower redistribution structure 110. Thereafter, by irradiating a laser to some regions of the solder resist layer SR1, openings that expose some regions of the lower redistribution pattern 111 disposed at a lowermost layer of the lower redistribution structure 110 may be formed. In another embodiment, if the solder resist layer SR1 is formed by applying a photosensitivity resin such as a photo-imageable dielectric (PID) on the lower surface of the lower redistribution structure 110, openings exposing some regions of the lower redistribution pattern 111 may be formed by a photolithography process. After the openings are formed, the UBM structure 160 that fills the openings may be formed through electroplating or electroless plating. In an embodiment, the UBM structure 160 may include copper (Cu), aluminum (Al), silver (Ag), tin (Sn), gold (Au), nickel (Ni), lead (Pb), titanium (Ti), or a metal material including an alloy thereof

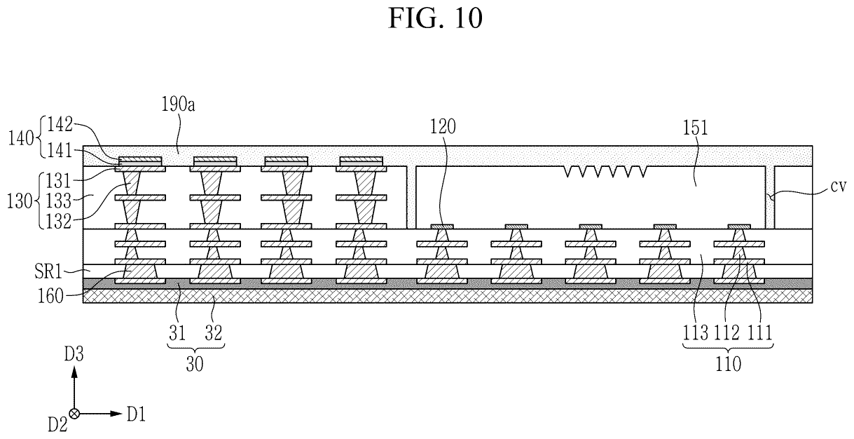

As shown in FIG. 10, the semiconductor package in which the lower redistribution structure 110, the solder resist layer 160, and the UBM structure 160 are formed may be attached to a third carrier 30. In this case, the semiconductor package may be turned over again so that lower surfaces of the solder resist layer 160 and the UBM structure 160 face downward, and then the semiconductor package may be attached to the third carrier 30 so that the lower surfaces of the solder resist layer 160 and the UBM structure 160 and an upper surface of the third carrier 30 contact each other. Accordingly, an upper surface of the preliminary encapsulation layer 190a may face upward (e.g., in the third direction D3). The third carrier 30 may include an adhesive layer 31 and a core layer 32 supporting the adhesive layer 31. The adhesive layer 31 may be formed of an adhesive polymer, and a release layer for peeling of the core layer 32 may be disposed between the adhesive layer 31 and the core layer 32. Subsequently, the second carrier 20 may be detached from the semiconductor package. After the second carrier 20 is removed from the semiconductor package, a cleaning process may be further performed to remove a foreign substance remaining in a region where the second carrier 20 is attached.

As shown in FIG. 11, some regions of the preliminary encapsulation layer 190a may be removed to form the encapsulation layer 190 according to the embodiment.

Specifically, a portion of an entire region of the preliminary encapsulation layer 190a may be removed to expose the second metal pad 142 formed above the wiring pattern 131 disposed at an uppermost layer of the connection structure 130. Additionally, a back side of the first semiconductor device 151 may be exposed by removing the portion of the entire region of the preliminary encapsulation layer 190a.

In an embodiment, if the preliminary encapsulation layer 190a is a film-type insulating resin such as an Ajinomoto Build-up Film (ABF), some regions of the preliminary encapsulation layer 190a may be removed by a laser ablation process. In another embodiment, if the preliminary encapsulation layer 190a is a photosensitivity resin such as a photo-imageable dielectric (PID), some regions of the preliminary encapsulation layer 190a may be removed by a photolithography process.

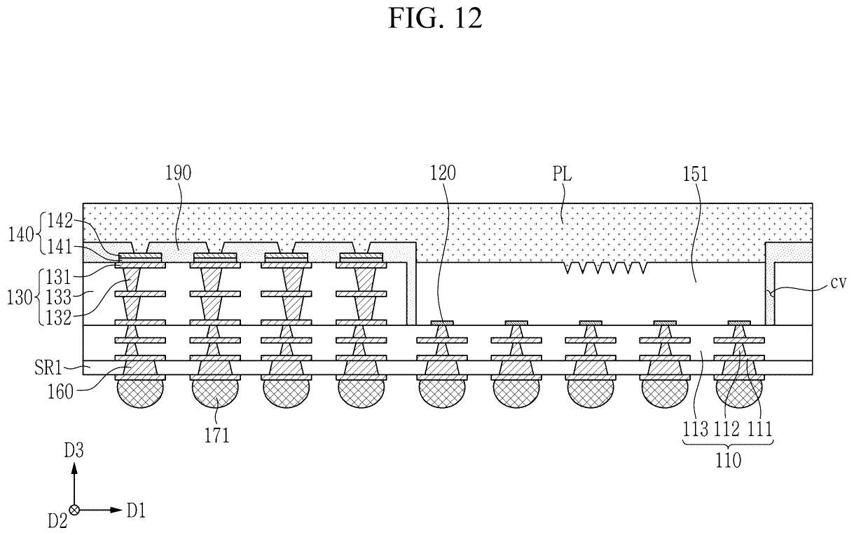

As shown in FIG. 12, after a protective layer PL covering upper surfaces of the encapsulation layer 190 and the first semiconductor device 151 is formed, a connection bump 171 may be formed on the lower surface of each UBM structure 160. In an embodiment, the protective layer PL may be temporarily formed to protect the first semiconductor device 151 and the second metal pad 142 in the process of forming the connection bumps 171, and may include an insulating material. For example, the protective layer PL may include a thermosetting resin such as an epoxy resin, a thermoplastic resin such as polyimide, or a resin (for example, prepreg, an Ajinomoto Build-up Film (ABF), FR-4, or BT) including the thermosetting resin or the thermoplastic resin impregnated with an inorganic filler or/and a glass fiber (a glass cloth or a glass fabric). The connection bumps 171 may include a metal material. For example, the connection bumps 171 may have a spherical or ball shape made of a low melting point metal such as tin (Sn), indium (In), bismuth (Bi), antimony (Sb), copper (Cu), silver (Ag), zinc (Zn), lead (Pb), an alloy (e.g., Sn—Ag—Cu) thereof, or the like.

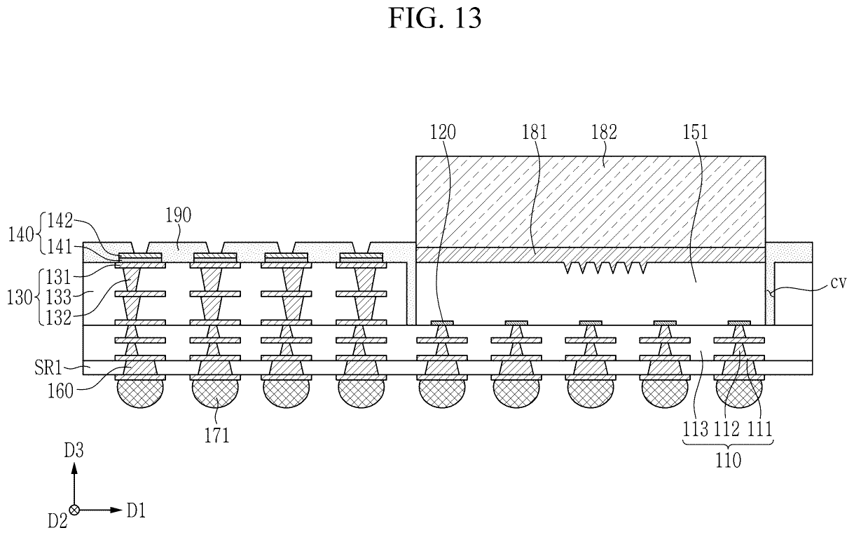

Thereafter, as shown in FIG. 13, after the protective layer PL is removed, the first heat dissipation member 181 and the second heat dissipation member 182 may be formed on the first semiconductor device 151. In an embodiment, the first heat dissipation member 181 may include an adhesive material. For example, the first heat dissipation member 181 may include a thermal interface material (TIM) such as a thermal conductive adhesive. In an embodiment, the first heat dissipation member 181 may fill the grooves formed at the back side of the first semiconductor device 151.

The second heat dissipation member 182 may be bonded to the back side of the first semiconductor device 151 through the first heat dissipation member 181. For example, the second heat dissipation member 182 may include a metal material such as copper (Cu), aluminum (Al), or an alloy thereof.

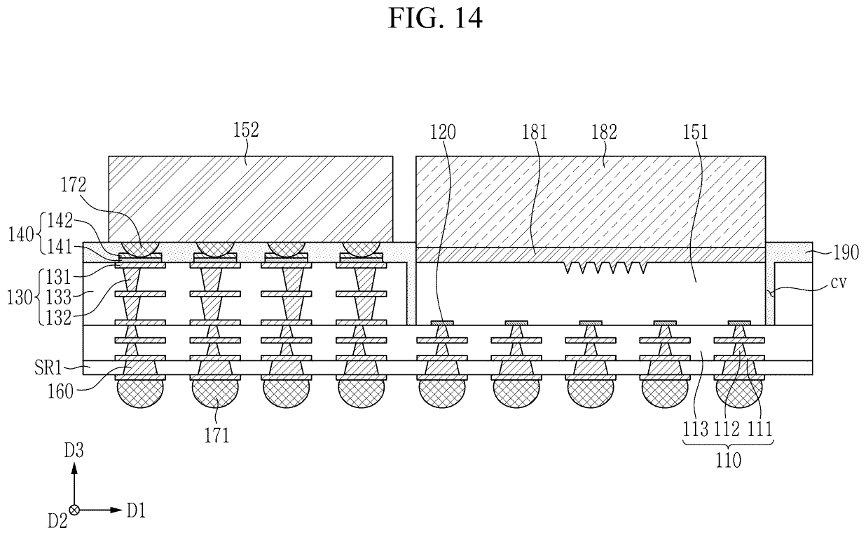

Subsequently, as shown in FIG. 14, the second semiconductor device 152 may be mounted on an upper portion of the connection structure 130. In an embodiment, the second semiconductor device 152 may be mounted on an upper surface of the connection structure 130 using a flip chip method. Specifically, the connection bumps 172 formed at the front side (i.e., active side) of the second semiconductor device 152 may be bonded to the metal pads 140 formed on surfaces of the wiring patterns 131 disposed at an uppermost layer of the connection structure 130.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a lower redistribution structure;
a solder resist layer that is disposed on a lower surface of the lower redistribution structure;
a connection structure that includes a cavity overlapping a portion of the lower redistribution structure and is disposed on the lower redistribution structure;
a first semiconductor device that is accommodated inside the cavity;
an encapsulation layer that covers a side surface of the first semiconductor device and an upper surface of the connection structure;
a first heat dissipation member that is disposed directly on the first semiconductor device and has a lower surface in contact with an upper surface of the first semiconductor device;
a second heat dissipation member that is disposed directly on the first heat dissipation member and has a lower surface in contact with an upper surface of the first heat dissipation member; and
a second semiconductor device that is disposed on the upper surface of the connection structure.

2. The semiconductor package of claim 1, wherein the encapsulation layer does not overlap the first heat dissipation member and the second heat dissipation member in a vertical direction.

3. The semiconductor package of claim 1, wherein the connection structure has a first sidewall and a second sidewall facing the first sidewall, and the cavity is disposed closer to the second sidewall than to the first sidewall.

4. The semiconductor package of claim 1, wherein the first semiconductor device includes a groove disposed on an upper surface thereof, and the groove is filled with the first heat dissipation member.

5. The semiconductor package of claim 1, wherein the second heat dissipation member has an upper surface disposed at the same vertical level as that of an upper surface of the second semiconductor device.

6. The semiconductor package of claim 1, wherein the connection structure comprises a plurality of wiring patterns spaced apart in a vertical direction, wiring vias connecting the wiring patterns, a first metal pad covering a portion of an upper surface of a wiring pattern disposed at an uppermost layer among the wiring patterns, and a second metal pad covering an upper surface of the first metal pad.

7. The semiconductor package of claim 6, wherein the first metal pad includes nickel (Ni) and the second metal pad includes gold (Au).

8. The semiconductor package of claim 1, wherein the first heat dissipation member includes an adhesive material, and the second heat dissipation member includes a metal material.

9. A method for manufacturing a semiconductor package, comprising:
forming, on a substrate, a connection structure including a cavity that exposes a portion of an upper surface of the substrate;
mounting a first semiconductor device inside the cavity;
forming an encapsulation layer covering the first semiconductor device and the connection structure;
forming a lower redistribution structure on lower surfaces of the connection structure and the first semiconductor device after the substrate is removed;
forming a solder resist layer on a lower surface of the lower redistribution structure;
removing some regions of the encapsulation layer that overlap the first semiconductor device in a vertical direction;
forming a first heat dissipation member in contact with an upper surface of the first semiconductor device at a region from which the encapsulation layer is removed;
forming a second heat dissipation member in contact with an upper surface of the first heat dissipation member; and
mounting a second semiconductor device on the connection structure.

10. The method of claim 9, wherein the encapsulation layer does not overlap the first heat dissipation member and the second heat dissipation member in a vertical direction.

11. The method of claim 9, wherein the connection structure has a first surface and a second surface facing the first surface, and the cavity is disposed closer to the second surface than to the first surface.

12. The method of claim 9, wherein the first semiconductor device includes a groove disposed on an upper surface thereof, and the groove is filled with the first heat dissipation member.

13. The method of claim 9, wherein the second heat dissipation member has an upper surface disposed at the same vertical level as that of an upper surface of the second semiconductor device.

14. The method of claim 9, wherein the connection structure comprises a plurality of wiring patterns spaced apart in a vertical direction, wiring vias connecting the wiring patterns, a first metal pad covering a portion of an upper surface of a wiring pattern disposed at an uppermost layer among the wiring patterns, and a second metal pad covering an upper surface of the first metal pad.

15. The method of claim 14, wherein the first metal pad includes nickel (Ni) and the second metal pad includes gold (Au).

16. The method of claim 9, wherein the first heat dissipation member includes an adhesive material, and the second heat dissipation member includes a metal material.

17. A semiconductor package comprising:
a lower redistribution structure;
a connection structure that includes a cavity overlapping a portion of the lower redistribution structure and is disposed on the lower redistribution structure;
a first semiconductor device that is accommodated inside the cavity;
a metal pad that is disposed directly on the first semiconductor device and has a lower surface in contact with an upper surface of the first semiconductor device;
a first heat dissipation member that is disposed directly on the metal pad and has a lower surface in contact with an upper surface of the metal pad;
a second heat dissipation member that is disposed directly on the first heat dissipation member and has a lower surface in contact with an upper surface of the first heat dissipation member; and
a second semiconductor device that is disposed on an upper surface of the connection structure.

18. The semiconductor package of claim 17, further comprising an encapsulation layer that covers a side surface of the first semiconductor device and the upper surface of the connection structure,
wherein the encapsulation layer does not overlap the metal pad, the first heat dissipation member, and the second heat dissipation member in a vertical direction.

19. The semiconductor package of claim 17, wherein the metal pad includes a groove disposed on an upper surface thereof, and the groove is filled with the first heat dissipation member.

20. The semiconductor package of claim 17, wherein the second heat dissipation member has an upper surface disposed at the same vertical level as that of an upper surface of the second semiconductor device.
